(19) United States
(12) Patent Application Publication
(10) Pub. No.: US 2025/0005220 A1
(43) Pub. Date: Jan. 2, 2025

(54) SYSTEM AND METHODS FOR DIGITAL TWIN SIMULATOR OF NATIONAL AIRSPACE SYSTEM

(71) Applicant: UNITED STATES OF AMERICA AS REPRESENTED BY THE ADMINISTRATOR OF NASA, WASHINGTON, DC (US)

(72) Inventors: JOSEPH L. RIOS, MOFFETT FIELD, CA (US); TODD A. LAUDERDALE, MOFFETT FIELD, CA (US); ROBERT D. WINDHORST, MOFFETT FIELD, CA (US); RICHARD A. COPPENBARGER, MOFFETT FIELD, CA (US); HEINZ ERZBERGER, MOFFETT FIELD, CA (US)

(21) Appl. No.: 18/757,490

(22) Filed: Jun. 27, 2024

Related U.S. Application Data
(60) Provisional application No. 63/510,631, filed on Jun. 27, 2023.

(51) Int. Cl. G06F 30/15

(52) U.S. Cl. CPC G06F 30/15

(57) ABSTRACT

System and methods for a digital twin simulator according to various aspects of the present invention operate in conjunction with a source of actual National Airspace System data, a testbed, a set of interfaces containing instructions on how to process archived data, a set of external components for processing the archived data according to the interfaces, and a simulator. The testbed receives archived National Airspace System data during a test and feeds the data to the external components. Processed results are forwarded to the simulator to run a simulation. The digital twin simulator may then compare differences between the simulated results and the archived National Airspace System data.

### CROSS-REFERENCES TO RELATED APPLICATIONS

This application claims the benefit of U.S. Provisional Patent Application No. 63/510,631, filed Jun. 27, 2023, and incorporates the disclosure of the application by reference.

### STATEMENT REGARDING FEDERALLY SPONSORED RESEARCH OR DEVELOPMENT

The invention described herein was made by employees of the United States Government and may be manufactured and used by or for the Government of the United States of America for governmental purposes without the payment of any royalties thereon or therefore.

### BACKGROUND OF THE TECHNOLOGY

The National Airspace System (NAS) is a complex system of systems. More specifically, the NAS comprises the navigation facilities and airports of the United States including the information, services, rules, regulations, policies, procedures, personnel, and equipment required to manage flight operations within the United States. This makes the NAS a challenging system to study and monitor due in large part to the volume of data passing through the NAS at any given point in time. Systems tasked with storing historical operational data are also large, complex, and distributed throughout the country.

Proposed improvements or changes to the NAS typically involve testing a given system separate and apart from the entire NAS. Traditional methods of testing a proposed change to a given system within the NAS often involve supplying that given system with a set of synthetic data which will produce a known result if the proposed change to the system is functioning correctly. Developing and running simulations of the NAS, or subsets of the NAS, are non-trivial. Even experienced engineering teams with cumulative decades of work with such simulations still must rely on that experience and the “art” of building the corresponding simulations. There are many assumptions that have to be discovered and documented with any given simulation. Two simulations of similar scenarios are typically difficult to compare due to these assumptions, available data, underlying software, underlying hardware, models of the components, and other issues. When the given system produces unexpected or undesired results, the system may be changed or modified according to the results. Subsequently, the given system must be tested again to determine if the changes bring about the expected results.

In another scenario, new features developed from technological improvements, which also require testing before the features may be released for use within the NAS, are desired to be added to a given system. A similar traditional testing protocol is typically used to validate these new features before they can be incorporated into the live NAS. This is an iterative process that is intended to maintain a desired level of safety and not disrupt the day-to-day operations of the NAS. By its nature, however, the iterative process is time consuming, expensive, and can delay implementation of new technologies, management protocols, and safety measures. An improved system or method is desired for implementing changes and improvements to the NAS.

### BRIEF SUMMARY OF THE TECHNOLOGY

System and methods for a digital twin simulator according to various aspects of the present invention operate in conjunction with live and historical National Airspace System (NAS) data, a central testbed, a component manager, an execution manager, and a simulation manger. A dedicated application programming interface (API) is used to facilitate communication between various distributed external components and the testbed. The testbed receives NAS data during a test and feeds the data to the simulation manager for use with a digital twin of the NAS system. The digital twin of the NAS system may have access to each system making up the NAS system or a replica of a given system within the NAS such that the digital twin represents an exact duplication of the actual (live) NAS system but is offline and not directly connected to the NAS. The simulation manager may then interact with one or more component managers to run a simulation to determine how the digital twin NAS system responds to a combination of actual NAS data and portions of NAS data swapped with simulated data as opposed to a purely simulated set of data. The digital twin simulator may then compare differences between the test results produced by the digital twin NAS system and the actual known outcome of the live NAS system associated with the NAS data used to run the simulation. The simulator manager may be also configured to extend a simulation beyond the received NAS data to simulate how the digital twin NAS system might behave over a longer term or set period of time. These results can then be compared or extrapolated to the actual NAS.

One embodiment of the technology is to provide a live, virtual, and constructive environment to quantify proposed changes to the NAS in terms of benefits, risks, validation, and verification of new technologies and algorithms. This motivates the need for a digital twin NAS system that is amenable to integration of new elements (e.g., a type of aircraft, new commercial flight routes, modified scheduling rules, increased traffic, autonomous aircraft, etc.) in place of known historical data that allows for common metrics to be generated across such activities.

Another embodiment of the technology is to create a high-fidelity model of proposed autonomous systems that can interact with a valid digital twin of the NAS to serve as a vital step in the validation of those proposed autonomous systems in a realistic environment that does not impact the safety or operation of the live NAS.

Another embodiment of the technology is for a digital twin NAS system that can accelerate the generation of test data to more fully explore the potential costs and benefits of certain research or proposed system changes to the NAS.

Another embodiment of the technology is to provide a digital twin NAS system running in parallel with the live NAS, with data from the real-world continually feeding the NAS Digital Twin to make it feasible to run multiple “what-if” exercises to improve the decision-making for current operations based on possible future events. For example, the digital twin NAS system could be used to determine what would happen to traffic within an area if a particular route is closed, what might occur if capacity is reduced on a given runway at an active airport, or what will happen to flight operations if a weather patterns moves to a specified location within a given timeframe.

Another embodiment of the technology is for a digital twin NAS system to allow for researchers or other users to specify a proposed change about flight operations and evaluate these proposed changes using selectable mixes of historical data and simulated aircraft in place of the actual aircraft that generated or were used to generate at least some of the historical data.

Another embodiment of the technology is for a digital twin NAS system to provide a distributed test platform that allows users to access the basic functionality of the NAS from different locations via a cloud-based network.

Another embodiment of the technology is for a digital twin NAS system to provide a distributed test environment in which test scenarios may be easily swapped in and out without impacting the core system.

These and other features, advantages, and objects of the present technology will be further understood and appreciated by those skilled in the art by reference to the following specification, claims, and appended drawings.

### BRIEF DESCRIPTION OF THE SEVERAL VIEWS OF THE DRAWINGS

FIG. 1 representatively illustrates a simplified view of elements making up a base system in accordance with an exemplary embodiment of the present technology;

FIG. 2 representatively illustrates a digital twin of the base system shown in FIG. 1 in accordance with an exemplary embodiment of the present technology;

FIG. 3 representatively illustrates a block diagram of a testbed for a digital twin simulation system in accordance with an exemplary embodiment of the present technology;

FIG. 4 representatively illustrates a block diagram of the testbed in accordance with an exemplary embodiment of the present technology;

FIG. 5 representatively illustrates a set of selected components from the testbed in accordance with an exemplary embodiment of the present technology;

FIG. 6 representatively illustrates a block diagram of a communication layer of the testbed in accordance with an exemplary embodiment of the present technology;

FIG. 7 representatively illustrates a component manager in accordance with an exemplary embodiment of the present technology;

FIG. 8 representatively illustrates a block diagram of a distributed test system in accordance with an exemplary embodiment of the present technology;

FIG. 9 representatively illustrates a results screen from a simulation in accordance with an exemplary embodiment of the present technology;

FIG. 10 representatively illustrates a graphical display of a created simulation in accordance with an exemplary embodiment of the present technology;

FIG. 11 representatively illustrates an airspace region for a simulation in accordance with an exemplary embodiment of the present technology;

FIG. 12 representatively illustrates a comparison between a simulated flight path and an actual flight path in accordance with an exemplary embodiment of the present technology;

FIG. 13 representatively illustrates an altitude comparison between a simulated aircraft flight and an actual aircraft flight in accordance with an exemplary embodiment of the present technology; and

FIG. 14 representatively illustrates a flight speed comparison between a simulated aircraft flight and an actual aircraft flight in accordance with an exemplary embodiment of the present technology.

### DETAILED DESCRIPTION OF EXEMPLARY EMBODIMENTS

For purposes of description herein, the terms “upper,” “lower,” “right,” “left,” “rear,” “front,” “vertical,” “horizontal,” and derivatives thereof shall relate to the technology as oriented in the corresponding figures. However, it is to be understood that the technology may assume various alternative orientations and step sequences, except where expressly specified to the contrary. It is also to be understood that the specific devices and processes illustrated in the attached drawings, and described in the following specification, are simply exemplary embodiments of the inventive concepts defined in the appended claims. Hence, specific dimensions and other physical characteristics relating to the embodiments disclosed herein are not to be considered as limiting, unless the claims expressly state otherwise.

The present technology may be described in terms of functional block components and various processing steps. Such functional blocks may be realized by any number of components configured to perform the specified functions and achieve the various results. For example, the present technology may employ various memory devices, processors, servers, databases, network communication protocols, and encryption systems, which may carry out a variety of operations. In addition, the technology described is merely one exemplary application for the disclosed system. Further, the present technology may employ any number of conventional techniques or methods of processing data, running simulations, comparing datasets, or manipulating any type of air system data received from a real-time data source, memory device, or simulated data set.

Systems and methods for a digital twin simulator according to various aspects of the present technology may operate in conjunction with any system or subsystem adapted for operation within the National Airspace System (NAS). Various representative implementations of the present technology may be applied to the testing of proposed improvements or changes to individual portions of the NAS such as air traffic control systems, flight management systems, airline planning systems, new aircraft testing, weather monitoring systems, and any other system that operates within the NAS. A digital twin simulator as detailed below may comprise a software platform or network that allows for different algorithms and capabilities to be integrated into a digital twinned offline version of the NAS for the purpose of using current and historical NAS operational data to obtain simulated results of the different algorithms and capabilities.

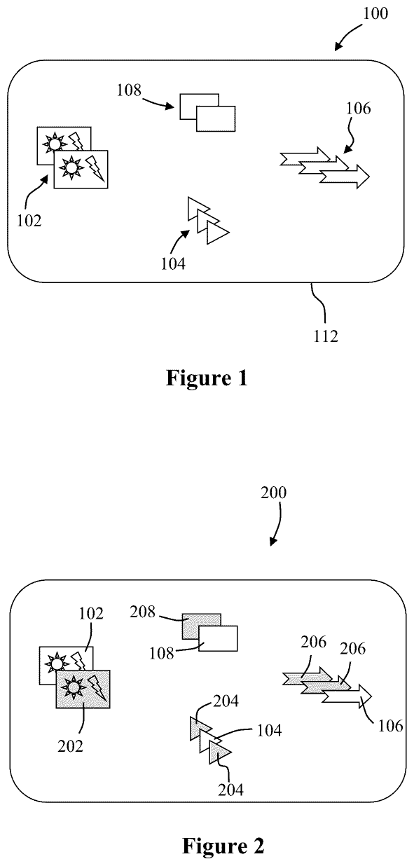

A digital twin simulator according to some embodiments of the present technology is configured to provide a complete digital copy of the individual systems that comprise the NAS to allow for the creation of offline simulations to test proposed changes to one or more individual systems based on actual historical data from the NAS or on real-time data from the NAS. Referring now to FIG. 1, the NAS 100 is composed of a collection of systems. Some systems, such as weather stations from various locations or airports 102 may act as a source of information used by other systems such as individual aircraft flight data 104, and airline operators 106. Other systems may include management systems 108 such as the FAA, air traffic control centers, flight traffic monitors, and the like. Operational data from each of these systems may be archived by a central information sharing platform such as the System Wide Information Management (SWIM) Program operated by the FAA.

Referring now to FIG. 2, a digital twin simulator may comprise a collection of digital copies of various individual systems, or the digital twin simulator may be configured to access archived SWIM data to create a virtual twin NAS system 200 to provide a virtual environment that may operate alongside the actual NAS 100, but is offline. The digital twin simulator may be configured to operate with live or archived data obtained from the central information sharing platform. The digital twin simulator may also be configured to use simulated data substituted in place of archived data. For example, the virtual twin NAS 200 may be able to access historical data saved from one or more weather stations 102. Simulated data may be substituted into a digital twin weather station 202 such that the simulated data may be used in place of actual historic data to test/simulate a proposed scenario. Similarly, the virtual twin NAS 200 may access actual historic aircraft flight data 104 corresponding to any desired criteria such as specific flights over known flight routes, arriving or departing flights from one or more airports, or flight parameters for specific types of aircraft at differing stages of flight. Flight data from simulated aircraft 204 may be substituted in place of the historic flight data or combined with the historic flight data to investigate any desired criteria such the impacts of additional traffic within a given region or operational changes based on a different type of aircraft or in-flight protocols. Likewise, actual airline operator 106 and management system 108 data may exist along with simulated airline operator 206 and management system 208 data.

The result is a virtual environment that is an exact twin of the actual operational system and is able to function identically to the actual NAS 100 system because it is based on and uses the same data archived from the actual NAS 100 system. A primary function of the virtual twin NAS 200 is that it will allow for changes to one or more systems to be simulated against the archived NAS 100 data and subsequently allow for a comparison between the simulated results and the actual results from the operational system. This creates a more realistic test environment without impacting the safety or operational status of the actual NAS 100. The digital twin simulator may also function in a distributed network environment, outside of the active system of the actual NAS 100, allowing for simulations to be performed remotely from multiple locations or from virtual machines on different elements simultaneously thereby increasing the speed and efficiency at which proposed changes or improvements to individual elements of the NAS 100 can be tested and evaluated. Such a digital twin simulator, while operating on a distributed network environment, is considered “offline” relative to the actual NAS 100, and is considered an “offline testing environment” for purposes of this description.

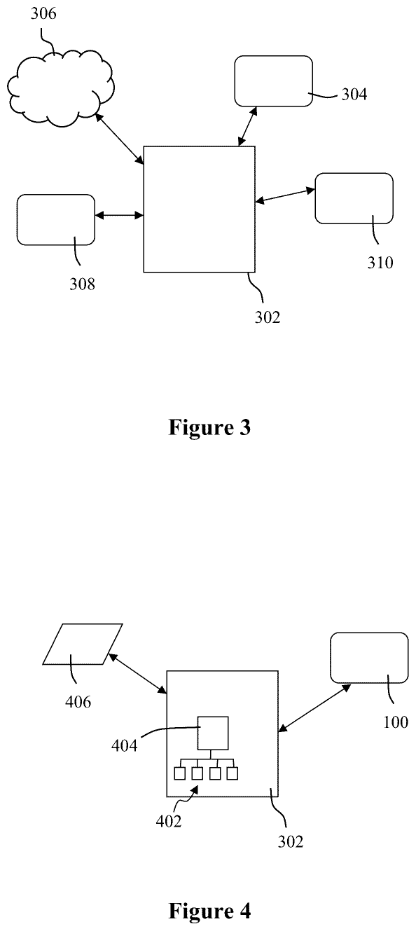

Referring now to FIG. 3, the digital twin system may further comprise a testbed simulation platform 302 to provide a connectivity framework for distributed simulation and a common communication language between simulation systems. For example, in some embodiments, the testbed 302 may be configured to communicate with one or more collaborators 310 that are able to remotely access the digital twin system to create and run simulations thereon, or analyze the results of a digital twin system simulation. The testbed 302 may also be configured to communicate with one or more external components 304, 306 that are configured to perform a specific calculation or processing of data according to a set of assigned interfaces. The external components 304, 306 may communicate with the testbed 302 by any suitable method such as a cloud-based web platform or via a local or wide area network. One or more simulators 308 may also access the testbed 302 to receive processed data from the external components 304, 306 to perform a simulation. In some embodiments, as will be discussed later, external components 304, 306 include, but are not limited to, the flight information for a plurality of airlines flying into the target airport during the time period in question, an aircraft flight manager, an air traffic viewer, a flight planner, and a FAA adapter. In some embodiments, external components 304, 306 are changed or improved external components that are being tested in the digital twin simulator.

With reference now to FIG. 4, the testbed 302 may comprise a plurality of interfaces 402 containing instructions that define the actions the external components 304, 306 will perform. For example, a given interface 402 may include specific protocols used by air traffic control centers to merge aircraft and to manage spacing between aircraft that are in flight. Another interface 402 may include protocols associated with the creation of a new flight plan, and yet another interface 402 may include a set of algorithms that can be used to simulate the flight of an aircraft based on a created flight plan. The interfaces 402 may also define the type of input data that is required to be received by a given external component 304, 306 to perform the required action and interfaces 402 may define the type of data that the external component 304, 306 will output as a result of the action. The output data may then be forwarded to the testbed 302 and subsequently passed to the simulators 308 for processing.

An application programming interface (API) 404 may be used to manage how each interface 402 functions and communicates with a particular data source. For example, one interface 402 may be configured to receive historical NAS data from a database 406 comprising many years' worth of NAS 100 flight data for individual aircraft flown in the United States. Another interface 402 may be configured to use specific types of real-time data as the data is being generated on the operational NAS 100 and saved to the SWIM system. The testbed 302 may be suitably configured to direct each type of data to the corresponding interface 402 in response to an appropriate command from the external components 304, 306 or the simulation manager.

In some embodiments, interface 402 defines actions that components perform, and defines data input into and output from external components 304, 306. In some embodiments, components 304, 306 can implement one or more interfaces 402, and is responsible for performing operations on the input data and outputting and returning any results.

In some embodiments, interfaces 402 include FlightStateProvider, which provides the state and intent for aircraft, AircraftManeuverListener, which listens to broadcast maneuvers, TrialPlanner, which creates predicted trajectories, AircraftSimulator, which allows new flights to be created and manuvered, EtaProvider, which provides predicted times at downstream points, and ScheduleAdvisor, which provides schedules at constrained resources.

In some embodiments, components 304, 306 include FlightManager, which performs trial planning to predict future trajectories, and simulates aircraft. FlightManager implements the interfaces FlightStateProvider, AircraftSimulator, AircraftManeuverListener, TrialPlanner, ScheduleAdvisor, and EtaProvider, and outputs to testbed 302 Track and FlightPlan data.

In some embodiments, components 304, 306 include Autoresolver, which separates aircraft similar to an air traffic controller. Autoresolver implements the interfaces ScheduleListener and SeparationProvider, and outputs Conflict and Trajectories to testbed 302.

In some embodiments, components 304, 306 include SwimFilePublisher, which plays back Swim data from Sherlock into Testbed Track and FlightPlan data. SwimFilePublisher implements no interfaces, and it outputs into testbed 302 Track and FlightPlan data.

In some embodiments, components 304, 306 include TrackListener, which listens to Testbed Track and FlightPlan data. TrackListener implements the interfaces FlightStateProvider and TrialPlanner, and receives as input Track and FlightPlan data, and outputs modified Track and FlightPlan data.

In some embodiments, components 304, 306 include CSMARTAdapter, which provides Schedules to constrained resources, where CSMART is Collaborative Seamless Manager of Airspace Resources and Traffic. CsmartAdapter interfaces with ScheduleAdvisor.

In some embodiments, a simulation is a collection of interfaces 402. A component that needs certain data to function would need to receive the data from an available interface 402. The component needs to implement the interface that has the necessary data.

Each interface 402 may be adapted to provide a specific set of instructions for how a given data source is processed so that a desired result is achieved. An interface 402 may be created to provide any relevant instructions for achieving a desired result. For example, a first interface 402 may be adapted to provide a current state and intended future state for one or more aircraft in flight. Accordingly, the first interface 402 may require data for each aircraft in the simulation that corresponds to a given aircraft's current flight condition and an expected flight condition at a given point in the future. The first interface 402 may also provide an interval in which the current and expected flights state information will be reported or updated. A second interface 402 may be adapted to process broadcast maneuver information to provide details on current and expected maneuvers of one or more aircraft. A third interface 402 may be adapted to receive the processed results from the first and second interfaces 402 to predict the trajectories of each aircraft. A fourth interface 402 may then be adapted to process the trajectory data to predict when each tracked aircraft will arrive at a particular location.

The external components 304, 306 implement one or more interfaces according to a desired result. For example, a first external component 304, 306 may be configured to perform a function of an air traffic controller by maintaining a minimum separation distance between aircraft. To perform this function, the external component 304, 306 will require specific types of data from one or more interfaces 402. As another example, another external component 304, 306 may be configured to test a proposed new protocol to an air traffic control system and require a different set of data from one or more interfaces 402 which may include one or more of the same interfaces 402 used by the first external component 304, 306.

In response to a signal to begin a simulation, the interface 402 or the external component 304, 306 may signal the testbed 302 to download a set or subset of archived data from the central information sharing platform which can then be used by the external component(s) 304, 306 to perform the required action specified by the interface 402.

Returning to the example above, a given external component 304, 306 may be configured to interact with all four interfaces 402 to process the data. The external component 304, 306 may also be configured to process data for a predetermined amount of time and forward the results to a simulator 308 where the resulting flight path for each aircraft can be processed or displayed according to the type of simulation being run. The simulator 308 may also be configured to display or otherwise present a comparison of the simulation results against a known result from the same originating data based on the actual NAS 100 data.

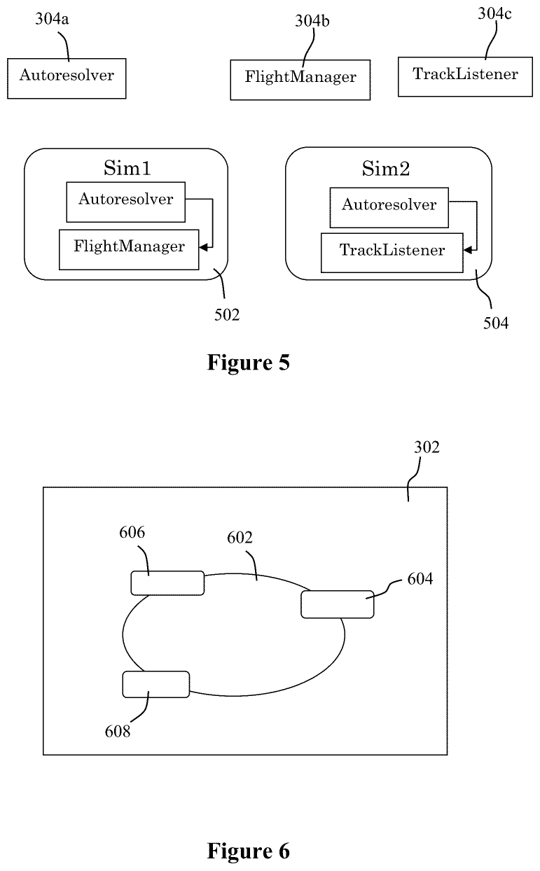

In one embodiment, and referring now to FIG. 5, when creating a simulation, external components 304, 306 may be selected according to the desired result. For example, a first external component 304a may provide state and intent information for each aircraft in a simulation. Second and third external components 304b, 304c may each implement the output data from the first external component 304a but may provide different results based on what underlying interfaces 402 are providing instructions to each of the second and third external components 304b, 304c. Accordingly, depending on a desired outcome, a collaborator 310 may be able to select the first external component 304a and either the second component 304b to run a first simulation 502 or the third external component 304c to run a different second simulation 504. Any additional number of external components 304, 306 may be selected according to the specific type of simulation that a user may want to run. In addition, a collaborator 310 may also be able to write a custom external component 304, 306 by selecting available interfaces 402 from a repository stored on the testbed 302.

The testbed 302 may further comprise a middleware layer 602 that facilitates communication between each external component 304, 306 across a communication network. The middleware layer 602 may comprise any suitable system for managing communication between external components 304, 306. In one embodiment, the middleware layer 602 may utilize a single communication protocol between external components 304, 306. In an alternative embodiment, the middleware layer 602 may be configured to facilitate communication between external components 304, 306 that use different communication protocols that otherwise would not be compatible with each other.

Referring now to FIG. 6, the middleware layer 602 may comprise a component manager 604 for managing each external component 304, 306, a simulation manager 606 for defining the parameters of the simulation and inputting the required data results into the simulator 308, and an execution manager 608 for processing the output data from the external components 304, 306. The simulation manager 606 may comprise any suitable system for managing the operation of a given simulation by the testbed 302. The simulation manager 606 may be configured to identify required data types, data sources, simulation parameters, or any other relevant information to a given simulation and provide it to the appropriate system. The simulation manager 606 may also be configured to allow a collaborator 310 to create a simulation by providing a user interface which can be used to create a simulation. For example, in one embodiment, the simulation manager 606 may display a list of available interfaces 402 along with a definition of what data each interface 402 requires as an input and what the output data will be after being processed by an external component 304, 306. The interface may also display available external components 304, 306 that may be selected and arranged to generate a simulation. The simulation manager 606 may also create a set of simulation information that contains the parameters of the simulation and the required data and interfaces 402 to perform the simulation.

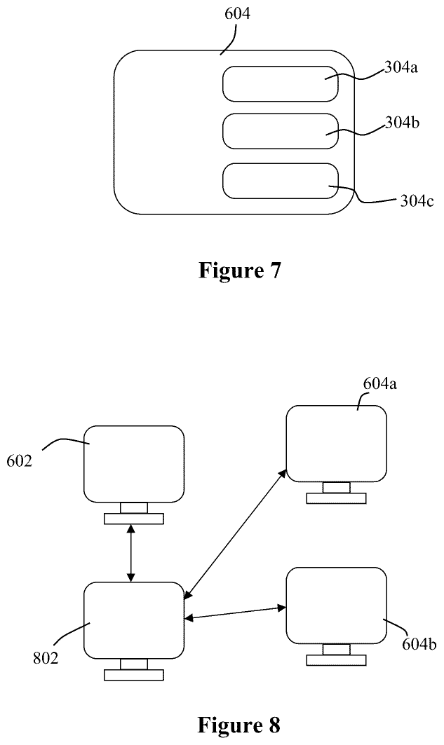

With reference now to FIG. 7, the component manager 604 may be configured to perform tasks associated with the management of each external component 304, 306. In one embodiment, the component manager 604 may be configured to receive the simulation information from the simulation manager 606 and identify which external components 304, 306 are required for the simulation. The component manager 604 may then download the identified external components 304, 306 from a repository on the testbed 302 or another memory device to a local or virtual machine for use. The component manager 604 may then manage the operation of each external component 304, 306 on the local machine according to the parameters in the set of simulation information.

Referring now to FIG. 8, a benefit of the distributed nature of the digital twin simulator is that the external components 304, 306 for a simulation are not required to be downloaded to the same local or virtual machine. Similarly, the component manager 604 is not required to reside on a single machine but may be distributed across more than one local or virtual machine. For example, a first component manager 604a may be located on or downloaded to a first virtual machine and be configured to manage a first set of external components 304, 306 downloaded to that virtual machine. A second component manager 604b may be downloaded to a second virtual machine to manage a second set of external components 304, 306. The middleware layer 602 may facilitate communication between each component manager 604a, 604b directly across a communication network or the middleware layer 602 may be able to provide instructions to the simulation manager resident on a third virtual machine 802 which then manages the communication of the first and second component managers 604a, 604b. This distribution allows each virtual machine to process only a portion of the data used in the simulation thereby reducing the workload on each virtual machine and distributing a potentially large portion of the processing away from the testbed 302 itself.

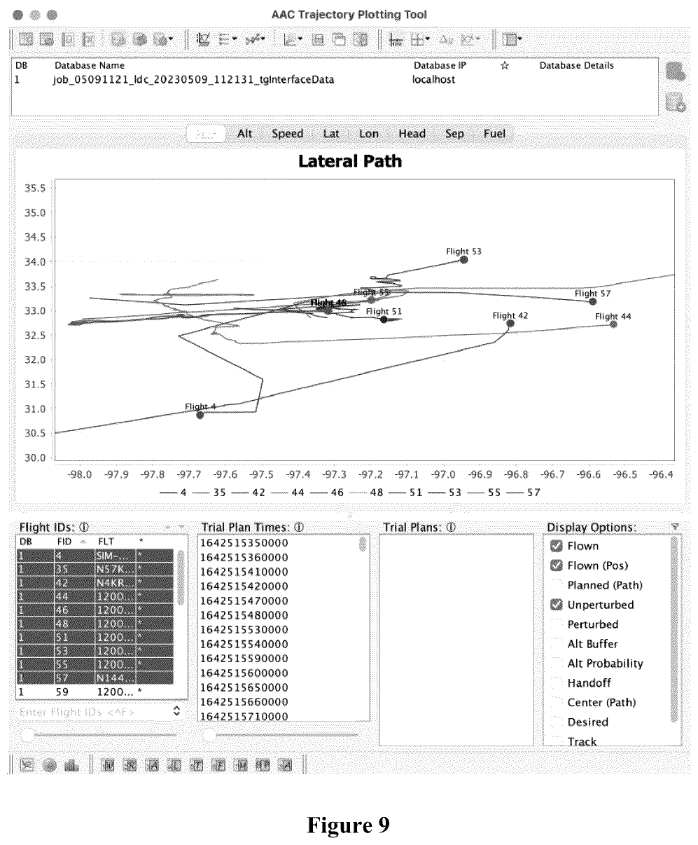

During a simulation, resulting data may be saved to a memory device linked to the testbed 302 or it may be saved to a local or virtual machine hosting the simulation manager 606. Data may be saved in any suitable format such as those used by spreadsheet software or other data analysis programs. Alternatively, the simulation manager 606, execution manager 608, or the testbed 302 may be configured to process the data and save the results into a database for later access or immediately display the results on one or more virtual machines. For example, and referring now to FIG. 9, in one embodiment, aircraft flight data resulting from a given simulation may be displayed for review. A user may be able to select one or more desired parameters for display allowing for a visual comparison of the simulation results.

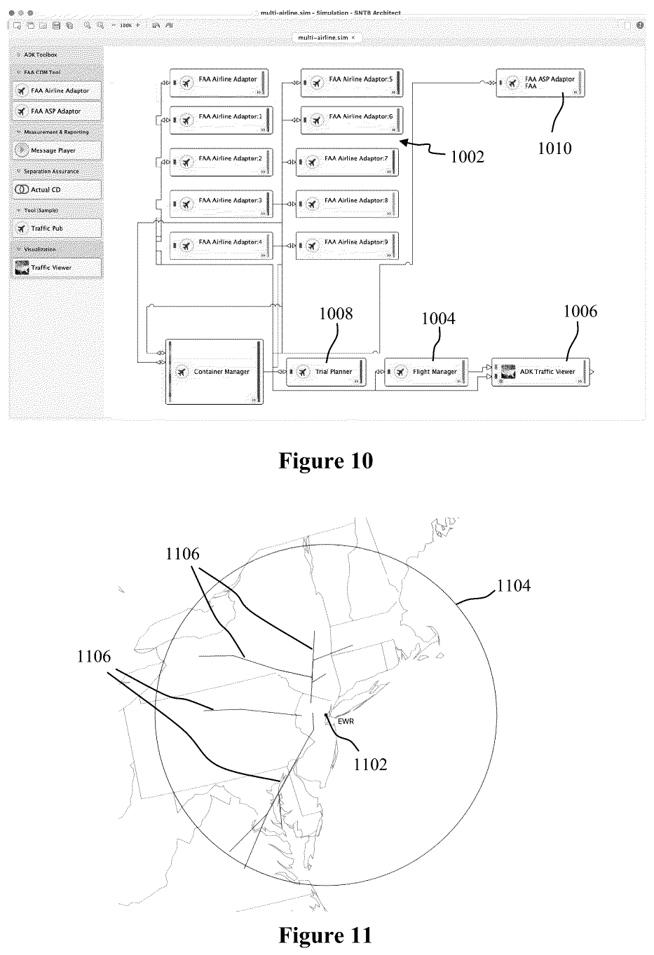

In a representative, but non-limiting example, the digital twin simulator may be used to compare the fuel-efficiency of arrival trajectories produced by a simulator for automated conflict resolution to the fuel-efficiency of arrival trajectories managed by air traffic controllers. In this scenario, historical flight data may be used to determine an initial set of conditions relating to the number of aircraft involved in the simulation, the known flight arrival trajectories of those aircraft as they enter a region around a target airport, the known flight management procedures used at that airport, and the amount of fuel used by those aircraft. For example, referring now to FIG. 10, the simulation may include a first set of external components 1002 corresponding to the flight information for a plurality of airlines flying into the target airport during the time period in question. Additional external components such as an aircraft flight manager 1004, an air traffic viewer 1006, a flight planner 1008, and a FAA adapter 1010 may be included to provide the necessary information and data to run the simulation.

In this scenario, the simulation involves a proposed change to the flight management of aircraft as they approach an airspace region around the target airport for arrival. The control sample, or controller-managed flights, are flown in the simulation according to the known historical data associated with each specific aircraft and its flight path on arrival. In contrast, the tested external component 304 was configured to maneuver automation-managed flights to meet arrival time constraints for the historical aircraft and to resolve conflicts, both against other automation-managed flights and controller-managed flights with an intended goal of reducing fuel consumption. During the simulation, the external component 304 had the ability to change the speed, altitude, or route of the automation-managed flights based on actions that would meet the intended goal.

Referring now to FIG. 11, the simulation was initiated on flights as they entered a predetermined airspace region 1104 around the target airport 1102. Known constraints such as approach routes 1106 to the target airport 1102, aircraft spacing requirements, and altitude requirements were applied to the automation-managed flights. Once an automation-managed flight entered into the airspace region 1104, the tested external component 304 was allowed to alter the flight paths of the incoming flights while also adhering to the known constraints.

In this example, the tested external component 304 was able to alter the flight paths of the automation-managed flights earlier than those of the controller-managed flights. This allowed for earlier intervention for merging maneuvers for incoming flights. A benefit of this is that the automation-managed flights maneuvers, such as slowing air speed or adjusting the flight path, were able to be performed at higher altitudes where the aircraft fly more efficiently. For example, because the tested external component 304 was able to compare an estimated time of arrival at the airport against a planned time of arrival for all arriving flights as soon as each aircraft crossed into the airspace region 1104, the tested external component 304 was able to take action for any aircraft that was predicted to have a conflict with another aircraft well before a given aircraft entered an area where a flight controller would normally be able to provide merging instructions.

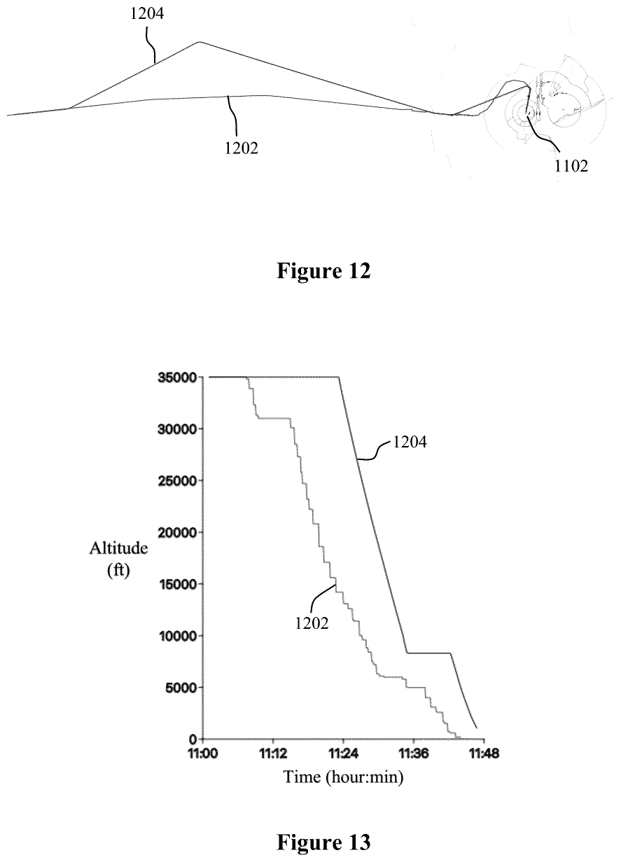

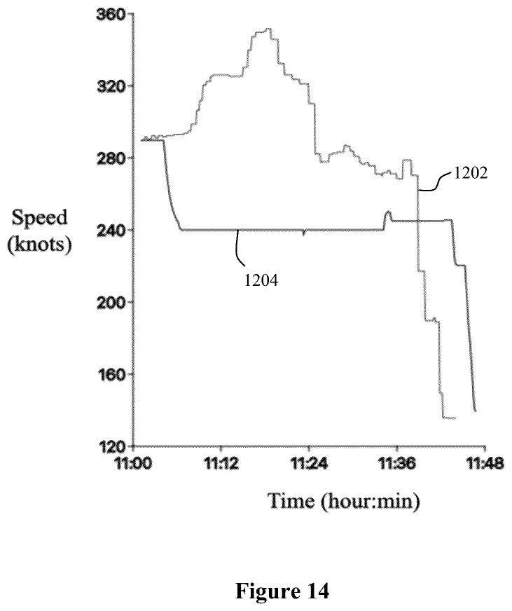

The result of earlier intervention of the automation-managed flights resulted in simpler flight maneuvers and less fuel burn. With reference now to FIGS. 12 and 13, a comparison of the flight path approach for a flight-controller managed flight 1202 and an automation-managed flight 1204 shows that merging maneuvers were initiated by the tested external component 304 further away from the target airport 1102 while the aircraft was at a higher altitude. This kept the automation-managed flight 1204 at higher altitudes for longer periods of time and required less maneuvering (e.g., leveling off) during descent. Referring now to FIG. 14, in addition to altering the flight path, the automation-managed flight 1204 was directed to reduce air speed sooner than the flight-controller managed flight 1202. The combination of these changes resulted in 712 lbs fuel-burn savings for this automation-managed flight 1204 compared to the controller-managed flight 1202. Additional fuel-burn savings were achieved on other flights in the simulation such that a preliminary result of the simulation demonstrated that earlier intervention for arriving aircraft could result in a large savings of fuel without causing delays in arrival time.

The testbed 302 allows for the results of the simulation for other individual aircraft to be examined as well as the cumulative effect of the change for all incoming flights. In addition, the simulation could be run again with a slight change to the parameters to compare results and determine if an optimum set of criteria can be determined for the target airport 1102. This scenario demonstrates the ability of the digital twin simulator to test a proposed change to the management of arrivals into a single airport to determine if the proposed change results in any benefit to fuel consumption while also ensuring that existing safety regulations are met such that the proposed changes could be tested in the real NAS 100 without impacting safety of live aircraft.

In another example, a set of external components 304, 306 may be adapted to receive historical data for all aircraft of a specified type meeting a predetermined set of conditions, such as flying above a certain altitude during a specific timeframe and within a specified region. The external components 304, 306 may then be used to run a simulation where each of the identified aircraft are replaced by an experimental aircraft which are then flown through the same trajectories to compare performance differences between the historical flights of actual aircraft and the experimental aircraft.

In yet another example, a set of external components 304, 306 may be adapted to receive historical data for all aircraft flying within an airspace of an international airport located in a large metropolitan urban area. The simulation may comprise the playback of all tracked aircraft flying within the area over a period of time. Another set of external components 304, 306 may then simulate the inclusion of one or more urban air mobility (UAM) operators within the same space to determine the potential for interactions between the tracked aircraft and the autonomously operated aircraft.

These and other embodiments for methods of a digital twin simulator may incorporate concepts, embodiments, and configurations as described above. The particular implementations shown and described are illustrative of the technology and its best mode and are not intended to otherwise limit the scope of the present technology in any way. Indeed, for the sake of brevity, conventional processing methods, network communication, data transfer, and other functional aspects of the system may not be described in detail. Furthermore, the connecting lines shown in the various figures are intended to represent exemplary functional relationships and/or physical couplings between the various elements. Many alternative or additional functional relationships or physical connections may be present in a practical system.

The description and figures are to be regarded in an illustrative manner, rather than a restrictive one and all such modifications are intended to be included within the scope of the present technology. Accordingly, the scope of the technology should be determined by the generic embodiments described and their legal equivalents rather than by merely the specific examples described above. For example, the components and/or elements recited in any apparatus embodiment may be assembled or otherwise operationally configured in a variety of permutations to produce substantially the same result as the present technology and are accordingly not limited to the specific configuration recited in the specific examples.

As used herein, the terms “comprises,” “comprising,” or any variation thereof, are intended to reference a non-exclusive inclusion, such that a process, method, article, composition or apparatus that comprises a list of elements does not include only those elements recited but may also include other elements not expressly listed or inherent to such process, method, article, composition or apparatus. Other combinations and/or modifications of the above-described structures, arrangements, applications, proportions, elements, materials or components used in the practice of the present technology, in addition to those not specifically recited, may be varied or otherwise particularly adapted to specific environments, manufacturing specifications, design parameters or other operating requirements without departing from the general principles of the same. Any terms of degree such as “substantially,” “about,” and “approximate” as used herein mean a reasonable amount of deviation of the modified term such that the end result is not significantly changed. For example, these terms can be construed as including a deviation of at least ±5% of the modified term if this deviation would not negate the meaning of the word it modifies.

The present technology has been described above with reference to exemplary embodiments. However, changes and modifications may be made to the exemplary embodiments without departing from the scope of the present technology. These and other changes or modifications are intended to be included within the scope of the present technology, as expressed in the following claims.

1. A digital twin simulation system for creating an offline testing environment of an active system with an archived set of historical operational data, comprising:
a testbed comprising a set of interfaces, wherein:
the testbed is configured to access the archived set of historical operational data to download one or more subtypes of operational data; and
each interface defines a set of instructions for processing the downloaded subtypes of operational data from the archived set of historical operational data;
an external component in communication with the testbed, wherein the external component is configured to:
receive instructions from at least one interface from the set of interfaces;
receive the downloaded subtypes of operational data from the testbed; and
process the received subtypes of operational data according to the instructions from the at least one interface, wherein at least a portion of the received subtypes of operational data is replaced with simulated data;
communicate the processed data to the testbed;
a simulation manager in communication with the testbed and configured to:
generate a set of simulation of information;
receive the processed data from the external component; and
perform a simulation according to the received data; and
an application programming interface (API) configured to facilitate communication between the testbed, the external component, and the simulation manager.

2. A digital twin simulation system according to claim 1, wherein the testbed further comprises a component manager configured to:
receive the set of simulation information from the simulation manager;
download a set of external components from the testbed according to the set of simulation information; and
signal each downloaded external component to begin processing the received operational data.

3. A digital twin simulation system according to claim 1, wherein the set of simulation information comprises:
a set of parameters of the simulation;
a set of the required subtypes of operational data;
a set of required interfaces; and
a set of required external components.

4. A digital twin simulation system according to claim 1, wherein the simulation manager is configured to provide a user interface to program a simulation.

5. A digital twin simulation system according to claim 1, wherein the testbed is further configured to access a source of real-time operational data and provide the real-time operational data to the external component.

6. A method of creating an offline testing environment of an active system with an archived set of historical operational data, comprising:
providing a testbed comprising a set of interfaces, wherein each interface from the set of interfaces defines a set of instructions for processing operational data;
downloading one or more subtypes of operational data from the archived set of historical operational data via the testbed;
forwarding the downloaded subtypes of operational data to one or more external components in communication with the testbed, wherein each external component is configured to:
receive instructions from at least one interface; and
process the received operational data according to the instructions from the at least one interface, wherein at least a portion of the received subtypes of operational data is replaced with simulated data; and
communicate the processed data to the testbed;
forwarding the processed operational data to a simulation manager;
performing a simulation with the simulation manager based on the processed operational data; and
facilitate communication between testbed, the external component, and the simulation manager with an application programming interface (API).

7. A method of creating an offline testing environment according to claim 6, wherein the simulation manager is further configured to generate a set of simulation information.

8. A method of creating an offline testing environment according to claim 6, wherein the set of simulation information comprises:
a set of parameters of the simulation;
a set of the required subtypes of operational data;
a set of required interfaces; and
a set of required external components.

9. A method of creating an offline testing environment according to claim 6, further comprising a simulation manager configured to:
receive the set of simulation information from the simulation manager;
download a set of external components from the testbed according to the set of simulation information; and
signal each downloaded external component to begin processing the received operational data.

10. A method of creating an offline testing environment according to claim 6, further comprising providing a user interface via the simulation manager to allow a simulation to be programmed.

11. A method of creating an offline testing environment according to claim 6, wherein the testbed is further configured to access a source of real-time operational data and provide the real-time operational data to the one or more external components.

12. A digital twin simulation system for creating an offline testing environment of an active system with an archived set of historical operational data to perform a simulation using one or more local machines, comprising:
a testbed comprising a set of interfaces, wherein:
the testbed is configured to access the archived set of historical operational data to download one or more subtypes of operational data; and
each interface defines a set of instructions for processing the downloaded subtypes of operational data from the archived set of historical operational data;
a plurality of external components in communication with the testbed, wherein each external component is configured to:
be downloaded to at least one of the local machines;
receive instructions from at least one interface from the set of interfaces;
receive the downloaded subtypes of operational data from the testbed; and
process the received subtypes of operational data according to the instructions from the at least one interface, wherein at least a portion of the received subtypes of operational data is replaced with simulated data;
communicate the processed data to the testbed;
a simulation manager in communication with the testbed and configured to:
generate a set of simulation of information;
receive the processed data from the plurality of external components downloaded to the local machines; and
perform a simulation according to the received data; and
an application programming interface (API) configured to facilitate communication between the testbed, the plurality of external components, the local machines, and the simulation manager.

13. A digital twin simulation system according to claim 12, wherein the testbed further comprises a component manager configured to:
receive the set of simulation information from the simulation manager;
download plurality of external components from the testbed to the one or more local machines according to the set of simulation information; and
signal each downloaded external component to begin processing the received operational data.

14. A digital twin simulation system according to claim 13, wherein the testbed is further configured to access a source of real-time operational data and provide the real-time operational data to the plurality of downloaded external components.

15. A digital twin simulation system according to claim 12, wherein the set of simulation information comprises:
a set of parameters of the simulation;
a set of the required subtypes of operational data;
a set of required interfaces; and
a set of required external components.

16. A digital twin simulation system according to claim 12, wherein the simulation manager is configured to provide a user interface to program a simulation.
